(19) United States
(12) Patent Application Publication
(10) Pub. No.: US 2010/0047594 A1
(43) Pub. Date: Feb. 25, 2010

(54) EQUIPMENT AND METHOD FOR PHYSICAL VAPOR DEPOSITION

(76) Inventors: Aharon Inspektor, Pittsburgh, PA (US); John J. Prizzi, Greensburg, PA (US)

Correspondence Address: KENNAMETAL INC.;Intellectual Property Department, P.O. BOX 231, 1600 TECHNOLOGY WAY, LATROBE, PA, 15650, US

(21) Appl. No.: 12/194,866

(22) Filed: Aug. 20, 2008

(51) Int. Cl. B32B 15/00; C23C 14/34; C23C 14/50

(52) U.S. Cl. 428/457; 204/298.02; 204/298.15; 204/192.12

(57) ABSTRACT

A physical vapor deposition apparatus for coating a substrate that includes a substrate holder that receives the substrate and a coating material source that emits a divergent stream of coating material. The divergent stream of coating material includes a diverse portion of coating material and a directed portion of coating material. The apparatus further includes a blinder means, positioned to be in operative engagement with the coating material source, for receiving and impacting the divergent stream of coating material so that the directed portion of coating material continuously exits the blinder means traveling generally toward the substrate holder. The directed portion of coating material exhibits less divergence than the divergent stream of coating material.

### BACKGROUND OF THE INVENTION

The invention pertains to equipment and a method for deposition of material via physical vapor deposition (PVD) techniques. More particularly, the invention pertains to equipment and a method for the deposition via PVD of one or more coating layers on a substrate, and especially nanolayer coatings, wherein the coatings exhibit improved periodicity of the coatings and/or sharp distinct boundaries between the coating layers.

Heretofore, PVD techniques have been useful for the deposition of one or more coating layers on a substrate. One exemplary kind of substrate is a substrate that, when coated with an appropriate coating material, is useful as a cutting tool in metalcutting (or other material removal) applications including (without limitation) chipforming material removal applications. The following documents disclose the use of PVD techniques to produce coated cutting tools: U.S. Pat. No. 5,879,823 to Prizzi et al. for a Coated Cutting Tool. The identification of this patent is not intended to limit the scope of the invention, but merely shows representative articles that are suitable for coating via PVD. This patent is hereby incorporated by reference herein.

PVD techniques are useful for the deposition of nanolayers of coating material. Typically, a single nanolayer has a thickness equal to or less than about 100 nanometers. Documents exemplary of the PVD deposition of coating nanolayers are U.S. Pat. No. 6,660,133 to Penich et al. for Nanolayered Coated Cutting Tool and Method for Making the Same and U.S. Pat. No. 6,884,499 to Penich et al. for Nanolayered Coated Cutting Tool and Method for Making the Same. The identification of these documents is not intended to limit the scope of the invention, but merely show representative examples of coating nanolayers applied by PVD. These patents are hereby incorporated by reference herein.

In reference to descriptions of PVD processes, the publication Handbook of Physical Vapor Deposition (PVD) Processing by Donald Mattox (1998) (published by Noyes Publications, Westwood, N.J. USA) generally describes the PVD process. In general, the PVD processes are atomistic deposition processes in which material is sputtered or vaporized from a solid or liquid source in the form of ions, atoms or molecules, transported through and often reacts with a low pressure plasma environment to the substrate where it condenses and forms a film. PVD processes can be used to deposit films that have a thickness from a few nanometers to thousands of nanometers. PVD processes can also be used to deposit multi-layer films, graded composition deposits, very thick deposits and freestanding structures. PVD processes can be used to deposit a film that comprises the reaction product of the vaporized material and an ambient gas environment like for example, nitrogen that can react with vaporized titanium to deposit titanium nitride on the substrate.

The Noyes publication also describes a number of physical vapor deposition processes. These PVD processes include vacuum deposition or vacuum evaporation; sputter deposition, arc vapor deposition, and ion plating. In the sputter deposition process, there is the deposition of particles removed from a surface (“target”), by the physical sputtering process. Arc vapor deposition uses a high current, low-voltage arc to vaporize a cathodic electrode (cathodic arc) or anodic electrode (anodic arc) and deposit the vaporized material on a substrate. In ion plating, which is sometimes called Ion Assisted Deposition (IAD) or Ion Vapor Deposition (IVD), the depositing material may be vaporized either by evaporation, sputtering arc erosion or by decomposition of a chemical vapor precursor. All methods utilize concurrent or periodic bombardment of the depositing film to modify and control the properties of the depositing film.

In a vacuum deposition or vacuum evaporation process, the ions, atoms or molecules from a thermal vaporization source reach the substrate with minimal collisions with residual gas molecules in the deposition chamber. Vacuum deposition normally requires a vacuum of better than 10⁻⁴ torr.

While all the PVD coating techniques have been successful in coating a substrate, and even in coating a substrate with a coating scheme comprising multiple layers of different compositions, there remains a need to improve such a process. This is especially true with respect to overlap of coating materials that occurs at the boundary between adjacent coating layers.

More specifically, the coating material that dislodges from the target can travel in a somewhat spread out fashion, e.g., the coating material takes the form of a plume, sometimes described by cosinus law distribution. As a result, it is common that some portion of the coating material that is emitted from one target deviate from normal-to-target direction and may overlap the area of deposition of the coating material from another target. When all the targets (or cathodes) are of the same material, the overlap of coating material from each target helps homogenize the coating all over the load and thus it is desirable. However, in the case of targets that are of different materials, overlap of coating materials may produce adverse mixtures of coating materials and is undesirable because the actual nanolayer coating scheme deposited on the substrate would not correspond to the intended coating scheme.

We have found that the occurrence of overlap of different coating materials can result in less than optimum properties of the coating and impact the performance of the coating and coated article. This can be especially true for coated cutting tools wherein the coating functions in a key role relative to the performance (including useful life) of the cutting tool. As can be appreciated, different coating compositions can yield different performance results.

Moreover, sharp or distinct boundaries between layers can impact the properties of the coated cutting tool. A sharp or distinct boundary between layers can form a coating scheme with strong well-defined boundaries between the coating layers. These strong boundaries limit migration of defects between the layers to improve properties such as, for example, the hardness of the film, the resistance to microcracking and/or resistance to crack propagation in the film. Similarly, it is advantageous to have a distinct boundary between alternating coating layers to help maintain uniform periodicity and consistency between each period of the coating scheme. Coating schemes that contain nanolayer films, especially with strong well-defined boundaries between nanolayers, provide the opportunity to deign a wide range of coating schemes that exhibit different properties well-suited for different material removal applications.

As power/current settings of the PVD targets increase, deposition rates increase. However, as the power/current setting is increased, the overlap in the plumes from different composition targets (i.e., targets that have a composition different from one another) increases, resulting in an intermixing of the layers. This intermixing leads to a less distinct (or strong) boundary structure and therefore, less distinction in properties between the layers, especially where nanolayers are desired. This intermixing thus limits the advantages from nanolayer coating structures. This invention addresses this issue by allowing high power/current settings of the PVD targets (coating material sources) while maintaining the distinctiveness of adjacent layers particularly in a nanolayer structured coating.

It can thus be appreciated that it would be desirable to provide improved equipment, as well as an improved method, for the deposition of coating material, and especially coating materials of different compositions, via PVD techniques.

It would also be desirable to provide improved equipment, as well as an improved method, for the deposition of nanolayers of material via PVD techniques, especially with regard to a coating scheme that comprises alternating nanolayers or sequential nanolayers or even random organization of the nanolayers of different compositions. In this regard, it would be beneficial if such equipment and techniques reduced overlap between coating materials plumes from adjacent cathode sources whereby the nanolayers presented strong well-defined boundaries therebetween. It would also be advantageous if such equipment and techniques would allow for the control of the thickness of the nanolayers independent of other operating parameters of the coating reactor (e.g., the level of power to the cathodes, rotational speed of the turntables, the pressure and/or temperature in the chamber, and other like parameters).

### SUMMARY OF THE INVENTION

In a PVD coating process, it is common for the coating material plume from each cathode to spread out through the reactor chamber to overlap (or interfere) with one another in the area of coating deposition (i.e., the region in which the coating material impinges upon the substrate(s)). The extent of such overlap is dependent upon a number of factors such as, for example, the packing density of the substrates (e.g., cutting tool blanks) to be coated, as well as operating parameters like the power/current level to the targets. Such overlap is undesirable, and is especially undesirable when the cathodes (or targets) are of different material compositions because the nanolayer coating scheme does not correspond to the intended coating scheme. More specifically, coating material plume overlap leads to a lack of strong well-defined boundaries between separate nanolayers. Nanolayers that do not have strong well-defined boundaries between nanolayers allows for the migration of defects between the nanolayers. Nanolayers that do not have strong well-defined boundaries between nanolayers also result in nanolayers with inconsistent thickness, as well as an inconsistency in the periodicity of a nanolayer coating scheme.

In view of the above, one fundamental aspect of the invention is to provide PVD equipment, as well as a PVD method, that reduces the extent of coating material plume overlap in the region in which the coating material impinges upon the substrate(s) independent of the operating parameters of the coating apparatus (reactor). By achieving such reduction, the nanolayers will exhibit strong well-defined boundaries therebetween to help prevent the migration of defects between nanolayers. Further, the nanolayers will exhibit consistent controlled thickness and a consistent periodicity in the nanolayer coating scheme.

In one form thereof, the invention is a physical vapor deposition apparatus for coating a substrate. The apparatus comprises a substrate holder adapted to receive the substrate. The apparatus further includes a coating material source that emits a divergent stream of coating material comprising a diverse portion of coating material and a directed portion of coating material. The apparatus also includes a blinder means, positioned to be in operative engagement with the coating material source, for receiving and impacting the divergent stream of coating material so that the directed portion of coating material continually exits the blinder means traveling generally toward the substrate holder. The directed portion of coating material exhibits less divergence than the divergent stream of coating material.

In yet another form thereof, the invention is a physical vapor deposition apparatus for applying a coating scheme to a substrate. The apparatus comprises a substrate holder adapted to receive the substrate. The apparatus also includes a first coating material source that emits a first divergent stream of first coating material comprising a first diverse portion of first coating material and a first directed portion of first coating material. The apparatus further includes a first blinder means, positioned to be in operative engagement with the first coating material source, for receiving and impacting the first divergent stream of first coating material so that the first directed portion of first coating material exits the first blinder means traveling generally toward the substrate holder. The first directed portion of first coating material exhibits less divergence than the first divergent stream of first coating material. The apparatus further comprises a second coating material source that emits a second divergent stream of second coating material comprising a second diverse portion of second coating material and a second directed portion of second coating material.

In still another form thereof, the invention is a blinder for use in conjunction with a physical vapor deposition apparatus having a coating material source that emits a divergent stream of coating material having a diverse portion of coating material and a directed portion of coating material. The blinder comprises a blinder body that has a proximate end that receives the divergent stream of coating material. The blinder body further defines a window through which the directed portion of coating material continually passes. The blinder body has a distal end through which the directed portion of coating material exits the blinder body exhibiting less divergence than the divergent stream of coating material.

One aspect of the invention with reference to the blinder/blinder means, is that the blinders/blinder means cover approximately at least about fifty percent (50%) of the distance between the target and the substrate (e.g., cutting insert) at its closest approach to the target. More preferably, it is desirable that the blinders/blinder means cover approximately at least about seventy-five percent (75%) of the distance between the target and the substrate (e.g., cutting insert) at its closest approach to the target.

In yet another form thereof, the invention is a method of coating the surface of a substrate by physical vapor deposition comprising the steps of: providing a substrate holder adapted to receive the substrate; emitting a divergent stream of coating material from a coating material source wherein the divergent stream of coating material comprising a diverse portion of coating material and a directed portion of coating material; and providing a blinder that receives the divergent stream of coating material whereby the blinder blocks the diverse portion of coating material from exiting the blinder and allows the directed portion of coating material to exit the blinder traveling generally toward the substrate holder whereby the directed portion of coating material exhibits less divergence than the divergent stream of coating material so that a substantial part of the directed portion of coating material impinges the substrate.

In yet another form thereof, the invention is a method of coating the surface of a substrate by physical vapor deposition comprising the steps of: providing a substrate holder adapted to receive the substrate; emitting a first divergent stream of coating material from a first coating material source wherein the first divergent stream of coating material comprising a first diverse portion of coating material and a first directed portion of coating material; providing a first blinder that receives the first divergent stream of coating material whereby the first blinder blocks the first diverse portion of coating material from exiting the first blinder and allows the first directed portion of coating material to exit the first blinder traveling generally toward the substrate holder whereby the first directed portion of coating material exhibits less divergence than the first divergent stream of coating material so that a substantial part of the first directed portion of coating material impinges the substrate; emitting a second divergent stream of coating material from a second coating material source wherein the second divergent stream of coating material comprising a second diverse portion of coating material and a second directed portion of coating material; and providing a second blinder that receives the second divergent stream of coating material whereby the second blinder blocks the second diverse portion of coating material from exiting the second blinder and allows the second directed portion of coating material to exit the second blinder traveling generally toward the substrate holder whereby the second directed portion of coating material exhibits less divergence than the second divergent stream of coating material so that a substantial part of the second directed portion of coating material impinges the substrate.

In still another form thereof, the invention is a physical vapor deposition coated article. The article comprises a substrate that presents a surface wherein a coating is on at least a portion of the surface of the substrate. The coating comprises a plurality of elements wherein each one of the elements is continuously emitted via physical vapor deposition from its separate source. The coating comprises a coating set of alternating nanolayers wherein one of the alternating nanolayers has a complete absence of one of the continuously emitted elements and another of the alternating nanolayers contains the element absent from the one alternating nanolayers.

### BRIEF DESCRIPTION OF THE DRAWINGS

The following is a brief description of the drawings that form a part of this patent application:

FIG. 1 is a mechanical schematic view of a PRIOR ART arrangement for depositing a coating scheme on a substrate wherein the coating scheme is a multilayer coating scheme that is deposited using three spaced-apart targets;

FIG. 2 is a mechanical schematic view of a first specific embodiment of the PVD arrangement of the invention for depositing a multilayer coating scheme on a substrate that is deposited using three spaced-apart cathodes wherein only one of the cathodes has a set of blinders positioned adjacent thereto;

FIG. 3 is an isometric view of a portion of the interior of the coating reactor represented by FIG. 2 that shows a pair of vertically aligned cathodes (out of a trio of vertically aligned cathodes) and wherein there is a pair of spaced-apart blinders positioned adjacent to each one of the cathodes;

FIG. 4 is a three-dimensional mechanical schematic view of the coating reactor represented by FIG. 2;

FIG. 5 is a mechanical schematic view of a second specific embodiment of the PVD arrangement of the invention for depositing a multilayer coating scheme on a substrate that is deposited using three a plurality of spaced-apart cathodes or targets wherein only one of the targets has a corresponding set of arcuate blinders;

FIG. 6 is a bar chart that depicts the impact that the spacing between the blinders (as reported in millimeters) has on the tool life (as reported in minutes) for Examples 1A, 1B and 1C in the turning of 316 stainless steel;

FIG. 7 is a bar chart that depicts the impact that the spacing between the blinders (as reported in millimeters) has on the number of passes before reaching a failure criteria for Examples 2A, 2B and 2C in the face milling of a solid block of 304 stainless steel;

FIG. 8 is a bar chart that depicts the impact that the electrical current to target (reported as either “high”, (which equates to 60 amps of electrical current), or (“low”, which equates to 40 amps of electrical current) has on the tool life (as reported in minutes) for Examples 3A, 3B, 3C and 3D in the GP turning of 316 stainless steel;

FIG. 9 is an EDS (energy dispersive spectrometry) line profile of a nanolayer coating scheme that comprises alternating nanolayers of titanium-aluminum-silicon-chromium nitride and titanium-aluminum-silicon-nitride, and that sets forth the content in atomic percent of aluminum (diamonds), silicon (squares), titanium (triangles) and chromium (circles) over a scan range equal to 40 nanometers wherein the blinders are adjacent to the chromium target and the electrical current to the chromium targets is 60 amps;

FIG. 10 is a photomicrograph performed via transmission electron microscopy (TEM) of the nanolayer coating scheme of FIG. 9 and the photomicrograph includes a legend of 20 nanometers;

FIG. 11 is a mechanical schematic (i.e., ray diagram) that shows the travel of coating material emitting from a coating material source of a pre-selected dimension and distance from the substrate when used in conjunction with a blinder assembly of a pre-selected axial length;

FIG. 12 is a mechanical schematic (i.e., ray diagram) that shows the travel of coating material emitting from a coating material source of a pre-selected dimension and distance from the substrate, which are the same as those for the apparatus of FIG. 11, when used in conjunction with a blinder assembly of a shorter axial length than the apparatus of FIG. 11;

FIG. 13 is a mechanical schematic (i.e., ray diagram) that shows the travel of coating material emitting from a coating material source, which has a coating material source with a smaller width than the coating material source of the apparatus of FIG. 11, located the same distance from the substrate as the apparatus of FIG. 11, when used in conjunction with a blinder assembly of the same axial length as the apparatus of FIG. 11; and

FIG. 14 is a mechanical schematic (i.e., ray diagram) that shows the travel of coating material emitted from a coating material source of a pre-selected dimension and distance from the substrate, which are the same as those for the apparatus of FIG. 12, when used in conjunction with a blinder assembly of the same axial length as the apparatus of FIG. 12, but with a second mediate window.

### DETAILED DESCRIPTION OF THE INVENTION

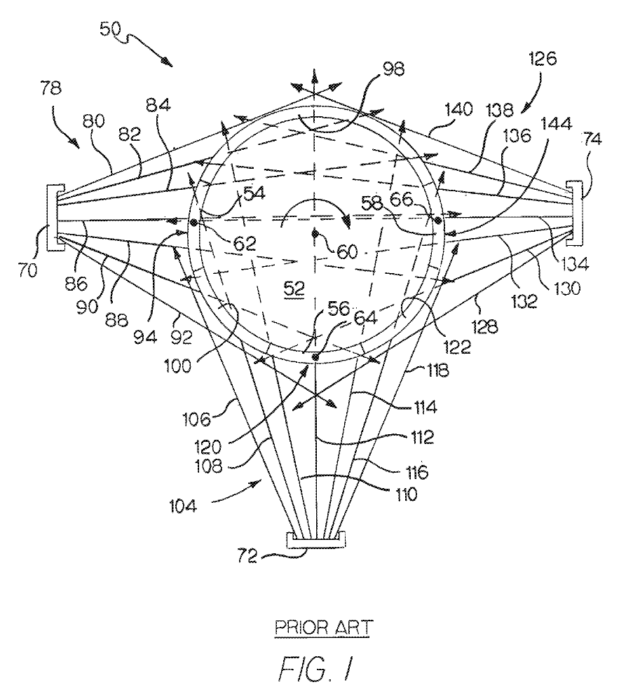

Referring to the drawings, FIG. 1 illustrates a mechanical schematic view of a PRIOR ART arrangement using an arc vapor PVD process for depositing a coating on a substrate. The prior art arrangement is generally designated as 50. The arrangement 50 as set forth in FIG. 1 is along the lines of a 3-axis rotational-stage-controlled deposition chamber as shown and described in the article by Hsieh et al. entitled “Deposition and characterization of TiAlN and multi-layered TiN/TiAlN coatings using unbalanced magnetron sputtering” in Surface and Coatings Technology, Vol. 108-109, (1998) at pages 132-137, which is incorporated by reference herein.

Prior art coating arrangement 50 includes a carousel arrangement that includes a primary turntable 52 (or like structure) that supports, as well as rotates, a plurality of rotatable secondary turntables (54, 56, 58) that carry one or more substrates (e.g., cutting tool blanks). In this arrangement, primary turntable 52 is rotatable about axis 60 in the direction (clockwise as viewed in FIG. 1) of the arrow. Each secondary turntable (54, 56, 58) is rotatable about its respective axis (62, 64, 66) in the clockwise direction as viewed in FIG. 1. The prior art arrangement 10 further includes a trio of stationary cathodes (or targets) (70, 72, 74).

In the operation of the prior art coating arrangement 50, the cathodes (70, 72, 74) are subjected to an electrical bias. Plasma develops that impinges each cathode to cause the emission of a coating material plume directed toward (or in the general direction of) the area of the primary turntable. Each coating material plume has a central portion and a peripheral portion. Typically, the central portion has a higher concentration of coating material than does the peripheral portion of the coating material plume. Further, as described hereinafter, the central portion of the coating material plume is directed toward a primary coating region relative to the specific cathode. The peripheral portion of the coating material plume is directed to pass wide of the primary coating region and toward adjacent intermediate coating regions relative to the cathode, as well as toward opposite areas of the coating reactor.

Cathode 70 emits a coating material plume generally designated as 78 (represented by arrows 80, 82, 84, 86, 88, 90, 92) in the general direction of the carousel arrangement. The central portion (represented by arrows 84, 86, 88) of the coating material plume 78 is emitted toward the primary coating region (see arrow 94) relative to the cathode 70. The primary coating region 94 is the region in the coating reactor that directly receives the central portion of the coating material plume 78 emitted by its corresponding cathode 70. When the secondary turntable 54 is in the primary coating region, i.e., the position shown by FIG. 1, the central portion of the coating material plume 78 directly impinges upon the substrates carried by the secondary turntable 54. As shown by the dashed sections of the arrows 84, 86, 88, a part of the central portion of the coating material plume 78 passes through the substrates and toward the opposite area of the coating chamber.

The coating material plume 78 also has a peripheral portion (represented by arrows 80, 82, 90, 92). The peripheral portion passes wide of the primary coating region 94 and then into other areas of the coating chamber including into the intermediate coating regions 98 and 100 located on either side of the primary coating region 94 relative to cathode 70. When the secondary turntable 54 is in the primary coating region, the peripheral portion of the coating material plume 78 typically does not directly participate in coating the substrates carried by the secondary turntable 54.

The operation of each one of cathodes 72 and 74 is the same as the operation of cathode 70. The following brief discussion will suffice for the description of cathodes 72 and 74.

Cathode 72 emits a coating material plume generally designated as 104 (represented by arrows 106, 108, 110, 12, 114, 116, 118). The central portion (represented by arrows 110, 112, 114) of the coating material plume 104 is emitted toward the primary coating region (se arrow 120) relative to the cathode 72. The coating material plume 104 also has a peripheral portion (represented by arrows 106, 108, 116, 118) that passes wide of the primary coating region 120 and then into other areas of the coating chamber including into the intermediate coating regions 100 and 122 located on either side of the primary coating region 120 relative to cathode 72. As shown by the dashed sections of the arrows 110, 112, 114, a part of the central portion of the coating material plume 104 passes through the substrates and toward the opposite area of the coating chamber.

Cathode 74 emits a coating material plume generally designated as 126 (represented by arrows 128, 130, 132, 134, 136, 138 140). The central portion (represented by arrows 132, 134, 136) of the coating material plume 126 is emitted toward the primary coating region (see arrow 144) relative to the cathode 74. The coating material plume 126 also has a peripheral portion (represented by arrows 128, 130, 138, 140) that passes wide of the primary coating region 144 and then into other areas of the coating chamber including into the intermediate coating regions 98 and 122 located on either side of the primary coating region 144 relative to cathode 74. As shown by the dashed sections of the arrows 132, 134, 136 a part of the central portion of the coating material plume 126 passes through the substrates and toward the opposite area of the coating chamber.

The primary turntable 52 rotates the substrates (as carried by the secondary turntables) to travel into and out of the primary and intermediate coating regions. When the substrates are in a primary coating region, they are primarily coated by the central portion of the coating material plume emitted by the cathode corresponding that that primary coating region. However, in the prior art coating apparatus 50, substrates in each primary coating region are also coated by peripheral portions of coating material plumes emitted by other cathodes. For example, the substrates carried by secondary turntable 56 are directly coated by the central portion (110, 112, 114) of the coating material plume 104 from cathode 72. These substrates are also coated (indirectly) by the peripheral portion (see arrow 128) of coating material plume 126 and the peripheral portion (see arrow 92) of coating material plume 78. Thus, it can be appreciated that even when the substrates are in the primary coating region, there can be overlap by the coating material plumes emitted from other cathodes.

When the substrates are located in an intermediate coating region, the substrates are not directly coated by any of the central portions of the coating material plumes, but are subject to being indirectly coated by extended sections of the primary portions, as well as by the peripheral portions, of the coating material plumes. For example, when a substrate is in intermediate region 122, it can be coated by the peripheral portion (see arrows 116, 118) of coating material plume 104, the peripheral portion (see arrows 128, 130) of coating material plume 126 and the extended section of coating material plume 78. The coating layers deposited on the substrates when they in the intermediate coating regions can exhibit differing compositions due to the intermixing of coating material plumes that occurs in the intermediate coating regions.

As can be appreciated by the PRIOR ART apparatus of FIG. 1, the coating material that dislodges from the target can travel in a somewhat spread out fashion. For example, the coating material dislodged from the target can take the form of a plume which is sometimes described by the cosinus law distribution. As a result, it is common that some portion of the coating material that is emitted from one target deviates from the normal-to-target direction and may overlap the area of deposition of the coating material from another target. When all the targets (or cathodes) are of the same material, the overlap of coating material from each target helps homogenize the coating all over the load, and thus, is actually a desirable feature.

However, in the case of targets that are of different materials, the occurrence of overlap of coating materials may produce adverse mixtures of coating materials. Such adverse mixtures of coating materials are undesirable because the actual nanolayer coating scheme deposited on the substrate would not correspond to the intended coating scheme. Overlap in the coating material plumes leads to a lack of strong well-defined boundaries between nanolayers. Nanolayers that do not have strong well-defined boundaries therebetween allow for the migration of defects between nanolayers. Nanolayers that do not have strong well-defined boundaries therebetween also result in nanolayers with inconsistent thickness, as well as an inconsistency in the periodicity of a nanolayer coating scheme.

The inventors have found that the occurrence of overlap of different coating materials can result in less than optimum properties of the coating and negatively impact the performance of the coating and coated article. This occurrence can be especially true for coated cutting tools wherein the coating functions in a key role relative to the performance (including useful life) of the cutting tool. As can be appreciated, different coating compositions can yield different performance results.

As will become apparent from the discussion below, the present invention provides PVD equipment, as well as a PVD method, that reduces the extent of coating material plume overlap in the primary coating region, as well as in the intermediate coating region, independent of the operating parameters of the coating apparatus (reactor). By achieving such reduction, the nanolayers exhibit strong well-defined boundaries therebetween to help prevent the migration of defects between nanolayers. Further, the nanolayers exhibit consistent controlled thickness and a consistent periodicity in the nanolayer coating scheme.

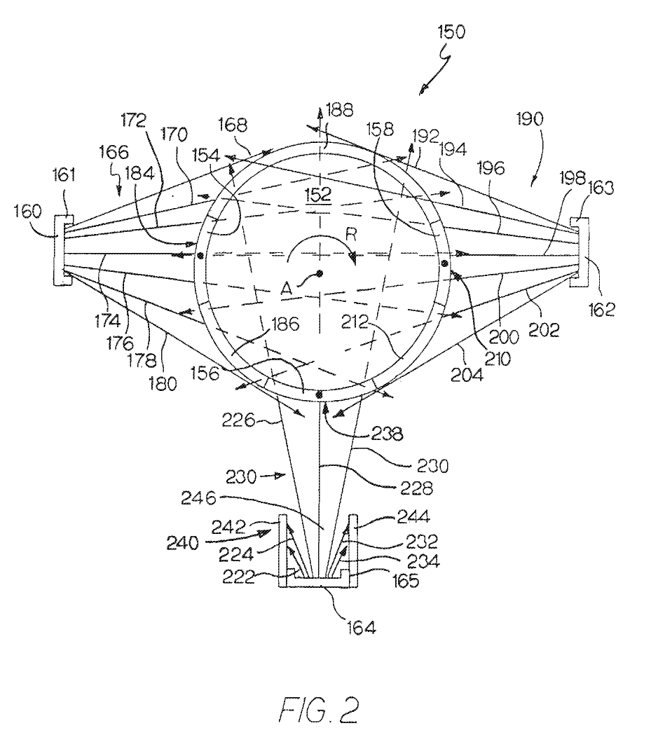

Referring to FIG. 2, there is illustrated in mechanical schematic form one specific embodiment of the PVD (arc vapor PVD method) coating apparatus (i.e., a physical vapor deposition apparatus for coating a substrate) generally designated as 150. Coating apparatus 150 is generally along the lines of a carousel arrangement disclosed in the article to Hsieh et al. wherein there is a coating chamber that contains the carousel, the blinders and the cathodes. Coating apparatus 150 includes a primary turntable (or stage) 152 that rotates about a central axis A in the direction of arrow R (clockwise as shown in FIG. 2) whereby the turntable(s) are movable with respect to the cathodes. The primary turntable 152 carries a trio of secondary rotatable turntables (or stages) 154, 156, and 158 wherein each one of the secondary turntables carries one or more substrates (e.g., cutting tool blanks) that are to be coated. Each secondary turntable (154, 156, 158) rotates in a clockwise direction (as viewed in FIG. 2) about its respective axis.

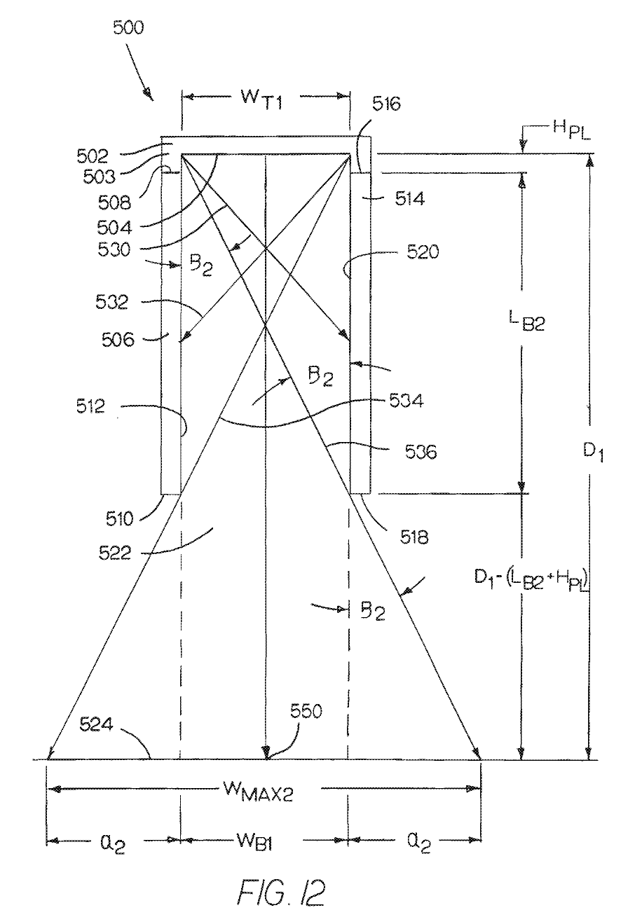

Coating apparatus 150 further includes a trio of stationary cathodes or targets (i.e., coating materials sources) 160, 162, 164 wherein cathode 164 has a blinder assembly associated therewith. It is typical for a coating material source to present a circular surface area from which the source emits a coating material plume (or divergent stream of coating material). Thus, the description of the width of the coating material source in reference to FIGS. 11-14 means that a lesser width correlates to a lesser surface area of the coating material source.

Applicant contemplates that more than one cathode can have a blinder assembly associated therewith. Applicant also contemplates that the coating apparatus may not use secondary turntables, but instead, the primary turntable may directly carry the substrate(s) to be coated. It should be appreciated that the structure that carries the substrate(s) (e.g., the primary turntable or the secondary turntable) may be considered to be a substrate holder adapted to receive the substrate(s).

Still referring to FIG. 2, cathode 160, which has a peripheral lip 161, emits a coating material plume generally designated as 166 (represented by arrows 168, 170, 172, 174, 176, 178, 180) in the general direction of the carousel arrangement. The central portion (represented by arrows 172, 174, 176) of the coating material plume 166 is emitted toward the primary coating region (see arrow 184) relative to the cathode 160. The primary coating region is the region in the coating reactor that directly receives the central portion of the coating material plume emitted by its corresponding cathode. When the secondary turntable 154 is in the primary coating region, i.e., the position shown by FIG. 2, the central portion of the coating material plume 166 directly impinges upon the substrates carried by the secondary turntable 154. One can characterize this condition as the substrate being in operative alignment with the coating material source. As shown by the dashed sections of the arrows, a part of the central portion of the coating material plume passes through the substrates and toward the opposite area of the coating chamber.

The coating material plume 166 also has a peripheral portion (represented by arrows 168, 170, 178, 180). The peripheral portion passes wide of the primary coating region 184 and then into other areas of the coating chamber including into the intermediate coating regions 186 and 188 located on either side of the primary coating region 184 relative to cathode 160. When the secondary turntable 154 is in the primary coating region, the peripheral portion of the coating material plume typically does not directly participate in coating the substrates carried by the secondary turntable 154.

Cathode 162, which has a peripheral lip 163, emits a coating material plume generally designated as 190 (represented by arrows 192, 194, 196, 198, 200, 202, 204) in the general direction of the carousel arrangement. The central portion (represented by arrows 196, 198, 200) of the coating material plume 190 is emitted toward the primary coating region (see arrow 210) relative to the cathode 162. The primary coating region is the region in the coating reactor that directly receives the central portion of the coating material plume emitted by its corresponding cathode. When the secondary turntable 158 is in the primary coating region, i.e., the position shown by FIG. 2, the central portion of the coating material plume 190 directly impinges upon the substrates carried by the secondary turntable 158. As shown by the dashed sections of the arrows, a part of the central portion of the coating material plume passes through the substrates and toward the opposite area of the coating chamber.

The coating material plume 190 also has a peripheral portion (represented by arrows 192, 194, 202, 204). The peripheral portion passes wide of the primary coating region 210 and then into other areas of the coating chamber including into the intermediate coating regions 188 and 212 located on either side of the primary coating region 210 relative to cathode 162. When the secondary turntable 158 is in the primary coating region, the peripheral portion of the coating material plume typically does not directly participate in coating the substrates carried by the secondary turntable 158.

Still referring to FIG. 2, cathode 164, which has a peripheral lip 165, emits a coating material plume generally designated as 220 (represented by arrows 222, 224, 226, 228, 230, 232, 234) in the general direction of the carousel arrangement. The central portion (represented by arrows 226, 228, 230) of the coating material plume 220 is emitted toward the primary coating region (see arrow 238) relative to the cathode 164. One can consider the coating material plume 220 to be a divergent stream of coating material since the directions in which the coating material travels are somewhat diverse. Although the divergent stream of coating material (i.e., the coating material plume) is generally in the direction of the substrate holder (e.g., the carousel arrangement).

One can consider the divergent coating material stream to have two basic portions; namely, a diverse portion of coating material and a directed portion of coating material. The diverse portion of coating material is that portion of the coating material emitted from the coating material source (e.g., cathode 164) that impinges or impacts the blinders, which are described hereinafter. In FIG. 2, the arrows 222, 224, 232 and 234 represent the diverse portion of coating material. The directed portion of coating material is that portion of the coating material emitted from the coating material source that does not impinge or impact the blinders, but instead, continually passes through the blinders and toward the primary coating region of the coating reactor. Arrows 226, 228 and 230 represent the directed portion of coating material.

The primary coating region is the region in the coating reactor that directly receives the central portion of the coating material plume (or the directed portion of coating material of the divergent stream of coating material) emitted by its corresponding cathode. When the secondary turntable 156 is in the primary coating region, i.e., the position shown by FIG. 2, the central portion of the coating material plume 220 directly impinges upon the substrates carried by the secondary turntable 156. As shown by the dashed sections of the arrows, a part of the central portion of the coating material plume passes through the substrates and toward the opposite area of the coating chamber.

Cathode 164 has a blinder means positioned to be in operative engagement therewith. The blinder means functions to continuously receive and impact the divergent stream of coating material so that the directed portion of coating material continuously exists the blinder means traveling generally toward the substrate holder. The blinder means comprises a blinder arrangement generally designated as 240 is comprised of adjacent blinders 242, 244 positioned near or about cathode 164. The preferred materials for use as blinders are stainless steels and other high temperature alloys. In a coating scheme in which coating layers have different compositions, it is preferred that the blinder arrangement is around (or in operative engagement with) the target (i.e., coating material source) that produces a coating layer in the coating scheme that is the softest coating layer. In this regard, the softest coating layer is typically the narrowest (or thinnest) coating layer in the coating scheme. However, there should be an appreciation that a blinder assembly may be in operative engagement with any one or more of the targets.

The blinders 242, 244 define a continuous window 246 (i.e., a window or opening that is continuously open or passable) between themselves. In this embodiment, the window is located at the distal end or termination of the blinders 242, 244. The central portion of the coating material plume 220 (or directed portion of coating material of the divergent stream of coating material) as represented by arrows 226, 228, 230 continually passes through the window 246 (or continually exits through the blinder assembly) toward the primary coating region 238 to impinge upon the substrates (i.e., directly coat) carried by the secondary turntable 156 when the coating apparatus is in the condition of FIG. 2.

The blinders 242, 244 limit the spread of the coating material plume 220 by functioning as a barrier that continuously impedes or blocks the travel of the peripheral portion of the coating material plume 220. In this regard, blinder 242 continuously impedes the travel that part of the peripheral portion of the coating material plume 220 (or diverse portion of coating material of the divergent stream of coating material) as generally represented by arrows 222, 224, 232 and 234. In this embodiment, the divergent stream of coating material has a central longitudinal axis that is generally parallel to the flat surfaces of the blinders 242, 244. It is typical for the blinders to be the same geometry and dimension. Thus, the description of the width of the blinders in reference to FIGS. 11-14 means that a lesser width between the blinders correlates to a lesser area through which the coating material passes.

One should appreciate that the blinders (242, 244) can be oriented so that the flat surfaces are not parallel to the central longitudinal axis of the divergent stream of coating material. FIG. 2 also illustrates that the blinders 242, 244 are closer to the coating material source than they are to the substrate holder.

By continuously impeding or blocking the travel of the peripheral portion of the coating material plume (or diverse portion of coating material), the blinders function to help prevent or reduce interfering or overlapping between the coating materials plumes emitted by the cathodes (i.e., coating material sources). For example, a part of peripheral portion of plume 220 (represented by arrows 232 and 234) is blocked by blinder 244 from traveling to overlap or interfere with coating material plume 190 from cathode 162. A part of peripheral portion of plume 220 (represented by arrows 222 and 224) is blocked by blinder 242 from traveling to overlap or interfere with coating material plume 166 from cathode 160. A reduction in the interference or overlap of the coating material plumes provides for the advantages and benefits described herein.

There should be an appreciation that the peripheral lip 165 of cathode 164, which is of a generally circular geometry, does not function to limit the spread of the coating material plume. The coating material plume 230 has significant divergence as shown by arrows 222, 224, 232 and 234 in FIG. 2. The peripheral lip 165 has no limiting effect on the portion of the coating material plume 230 as shown by arrows 222, 224, 232 and 234 in FIG. 2. Hence, the peripheral lip 165 of the cathode 164 is not a blinder. This is also the case for the cathodes (coating material sources or targets) of the other specific embodiments herein.

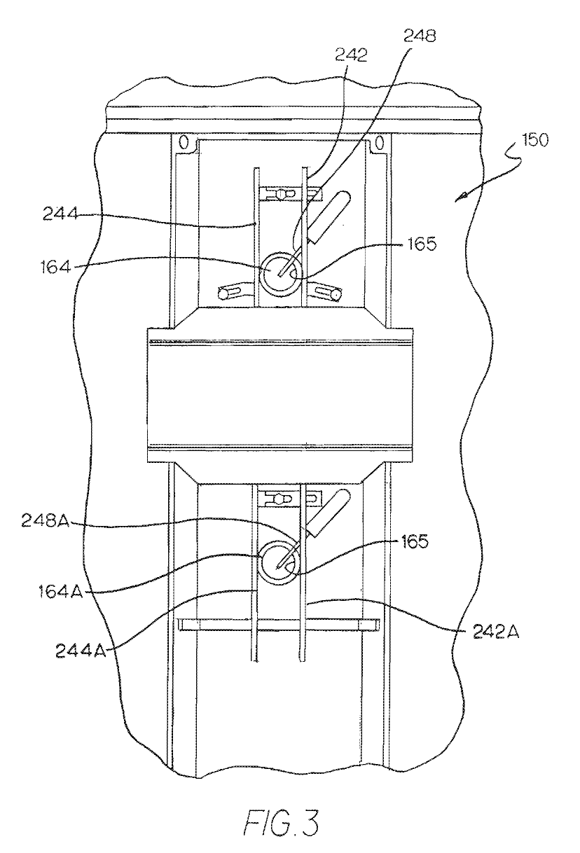

FIG. 3 is an isometric view of the interior of the coating reactor represented in FIG. 2 and generally designated as 150. In this view, coating reactor 150 includes a pair of cathodes (164, 164A) wherein cathodes are in vertical alignment as shown in the drawing (FIG. 3). Cathode 164 includes a peripheral lip 165. Cathode 164A also includes a peripheral lip 165A. Cathode 164 has a corresponding anode 248 and cathode 164A has a corresponding anode 248A. Cathode 164 has a pair of blinders 242, 244 positioned adjacent thereto. Blinders 242, 244 are generally parallel to one another, and are also generally parallel to the direction of travel of the path of the coating material plume generated by cathode 164 and directed to impinge the substrate. Cathode 164A has a pair of blinders (242A, 244A) positioned adjacent thereto wherein these blinders function in a fashion similar to the function of the blinders 242 and 244.

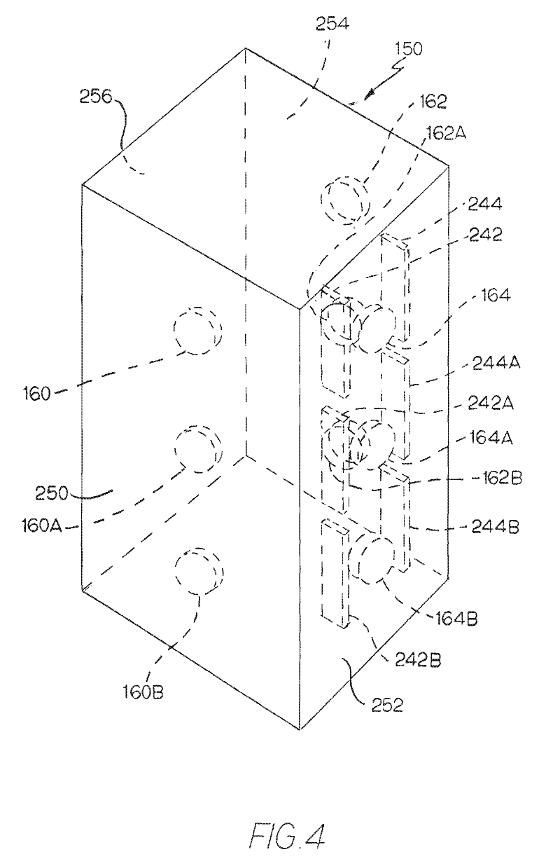

Referring to FIG. 4, there is shown in an isometric mechanical form, the coating reactor generally designated as 150. In this embodiment, there are four upstanding vertical walls (250, 252, 254, 256) wherein three of the walls (250, 252, 254) each contains a trio of vertically aligned cathodes. In this regard, wall 252 contains cathodes 164, 164A, 164B. Cathode 164 has blinders 242 and 244 positioned adjacent thereto. Cathode 164A has blinders 242A and 244A positioned adjacent thereto. Cathode 164B has blinders 242B and 244B positioned adjacent thereto. Wall 254 contains cathodes 162, 162A and 162B, and wall 250 contains cathodes 160, 160A and 160B. The fact that coating reactor 150 has four walls is not limiting to the scope of the invention. Applicant contemplates that the coating reactor could have a varying number of walls depending upon the application. In this regard, the coating reactor could have six walls or eight walls.

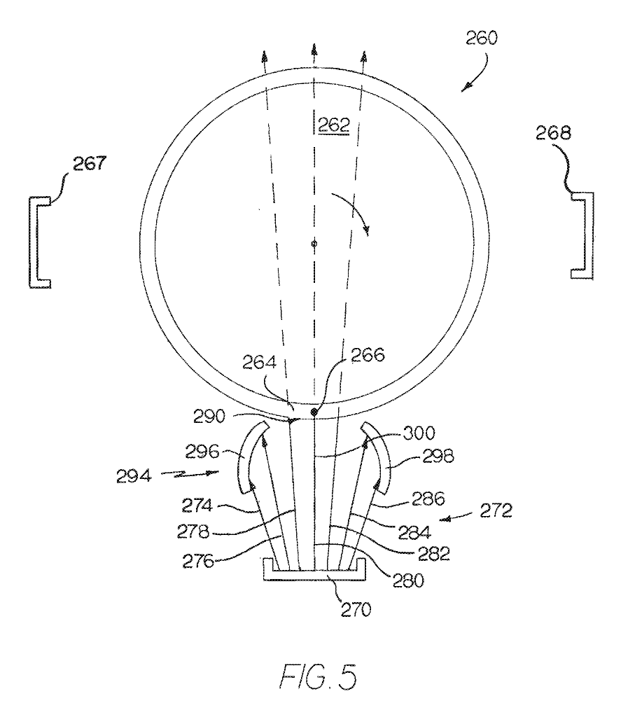

Referring to FIG. 5, there is illustrated in mechanical schematic form another specific embodiment of the PVD (arc vapor PVD method) coating apparatus generally designated as 260. Coating apparatus 260 is along the lines of a carousel arrangement disclosed in the Hsieh et al. article. One should appreciate that FIG. 5 illustrates in detail the cathode (or coating material source) 270 that has the blinders (296, 298) and the turntable (264). However, FIG. 5 shows only a general representation of the other cathodes 267, 268 without the representations of the material plumes. In this regard, the operation of each of the other cathodes (267, 268) is the same as that of cathodes 70 and 74 in FIG. 2 so that the description of cathodes 70 and 74 will suffice for the description of the other cathodes.

Coating arrangement 260 includes a primary turntable 262 that rotates about a central axis in the direction of the arrow (clockwise as shown in FIG. 5). While the primary turntable 262 carries a plurality of secondary turntables, FIG. 5 illustrates only secondary turntable 264, which rotates in a clockwise direction about axis 266. As with the embodiment of FIG. 2, the coating apparatus 260 has a plurality of stationary cathodes. Applicant has illustrated only cathode 270, which is the cathode that has blinders connected therewith. Like for the coating apparatus of FIG. 2, the primary turntable has a primary coating region that corresponds to each cathodes and an intermediate coating region between adjacent primary coating regions.

Cathode 270 emits a coating material plume generally designated as 272 (represented by arrows 274, 276, 278, 280, 282, 284, 286) in the general direction of the carousel arrangement. Along the general lines of the description in conjunction with the embodiment of FIG. 2, one can consider the coating material plume 270 to be divergent stream of coating material that has a diverse portion of coating material and a directed portion of coating material. The central portion (represented by arrows 278, 280, 282) of the coating material plume 272 (or directed portion of coating material) is emitted toward the primary coating region (see arrow 290) relative to the cathode 270. As described in conjunction with the coating apparatus 150, the primary coating region is the region in the coating reactor that directly receives the central portion of the coating material plume emitted by its corresponding cathode so that substrates in the primary coating region are directly coated by the central portion of the coating material plume.

The coating material plume 272 also has a peripheral portion (represented by arrows 274, 276, 284, 286) or a diverse portion of coating material. Unless blocked by the blinders, the peripheral portion would pass wide of the primary coating region and then into other areas of the coating chamber including into the intermediate coating regions and located on either side of the primary coating region relative to cathode. However, the blinder arrangement 294, which is a blinder means, functions to continuously receive and impact the divergent stream of coating material so that the directed portion of coating material continuously exits the blinder arrangement.

A blinder arrangement generally designated as 294 is comprised of adjacent arcuate blinders 296, 298 positioned near or about the primary coating region 290. The preferred materials for use as blinders are stainless steels and other high temperature alloys. The blinders 296, 298 define a continuous window 300 (i.e., a window or opening that is continuously open or passable) between themselves. Window 300 is at the distal end or termination of the blinders 296, 298. The central portion of the coating material plume 272 as represented by arrows 278, 280, 282 passes through the window 300 toward the primary coating region 290 to impinge upon the substrates carried by the secondary turntable 264 when the coating apparatus is in the condition of FIG. 5.

The blinders limit the spread of the coating material plume by functioning as a barrier that continuously impedes the travel of the peripheral portion of the coating material plume (or the diverse portion of coating material). In this regard, arcuate blinder 296 continuously impedes the travel that part of the peripheral portion of the coating material plume represented by arrows 274 and 276. Arcuate blinder 298 continuously impedes the travel of that part of the peripheral portion of the coating material plume represented by arrows 284 and 286. As described above in conjunction with the coating apparatus of FIG. 2, by continuously impeding the travel of the peripheral portion of the coating material plume, the arcuate blinders function to help prevent or reduce interfering or overlapping between the coating materials plumes emitted by the cathodes (i.e., coating material sources).

To reduce the overlap, it is beneficial to be able to control the width (or magnitude) of the directed portion of coating material in the region where the coating material impinges the substrate(s). The overall geometry including without limitation the size and positioning of the components of the coating apparatus influence the magnitude of the directed portion of coating material in the region where the coating material impinges the substrate(s). The magnitude of the directed portion of coating material that impinges upon the substrate(s) is of interest since a narrower or more focused directed portion of coating material results in a reduction in the overlap between coating material from adjacent coating material sources. In order to better explain and describe this influence, FIGS. 11 through 14 depicts in mechanical schematic form four different coating arrangements. Even though FIGS. 11 through 14 are two-dimensional drawings, they illustrate the principles and the way in which the overall geometry of the coating apparatus (which produces a three-dimensional divergent stream of coating material) influences the magnitude of the three-dimensional directed portion of coating material in the region where the coating material impinges the substrate(s).

FIG. 11 is a mechanical schematic (i.e., ray diagram) that depicts a portion of a coating apparatus generally designated as 400. FIG. 11 shows the travel of coating material emitting from a coating material source of a pre-selected dimension and pre-selected distance from the substrate(s) when used in conjunction with a blinder assembly of a pre-selected axial length. Coating apparatus 400 includes a coating material source (e.g., cathode) 402 that has a surface 404. Coating material source 402 has a peripheral lip 403. The height of the peripheral lip 403 is equal to H_{PL} as shown in FIG. 11. The width of the surface of the coating material source is W_{T1}. The width of the coating material source (W_{T1}) is equal to the width of the blinder (W_{B1}).

The apparatus 400 further includes a first blinder 406 that has a proximate end 408 that is proximate to the coating material source and a distal end 410 that is distal from the coating material source. Blinder 406 has an interior surface 412. The apparatus further includes a second blinder 414 that has a proximate end 416 that is proximate to the coating material source and a distal end 418 that is distal from the coating material source. Blinder 414 has an interior surface 420. The blinders 406 and 414 are of an equal axial length L_{B1}. In view of the peripheral lip 403, the blinders 406, 414 extend a distance L_{B1}+H_{PL} from the surface 404 of the coating material source 402.

The pair of blinders 406, 414 defines between them a window 422 that is at their distal ends. Region 424 is the region in the coating chamber in which the coating material impinges upon the substrate(s). The distance between the surface of the coating material source and the region in which the coating material impinges upon the substrate(s) is equal to D₁.

When the coating material source 402 is operational, a divergent stream of coating material continually emits from the coating material source. Arrows 430, 432, 434 and 436 schematically represent the divergent stream of coating material. The divergent stream of coating material has a directed portion of coating material, which comprises the coating material that is within the boundary or periphery as represented by the arrows 434 and 436. These arrows 434 and 436 extend from the corners of the coating material source to the distal ends of the opposite blinders, and thus, represent the periphery of the directed portion of the coating material that exits the blinder assembly. The periphery is oriented at an angle of divergence β₁ relative to the interior surfaces of the blinders. As one can appreciate, β₁ is less than the angle of divergence of the entire divergent stream of coating material. The divergent coating material stream also includes a diverse portion of the coating material. The diverse portion of the coating material comprises the coating material emitted from the coating material source that impinges upon the blinders. The coating material as represented by arrows 430 and 432 is within the diverse portion of coating material.

As stated above, the magnitude of the directed portion of coating material that impinges upon the substrate(s) is of interest. In an arrangement like that shown by FIG. 11, the dimension W_{MAX1} represents the total magnitude of the directed portion of coating material in the region where the coating material impinges the substrate(s). This magnitude is of interest in that there is more overlap when the magnitude is greater. There is, of course, less overlap when the magnitude is smaller. The distance on each side of the width of the blinder (W_{B1}) is equal to a₁ due to the symmetry of this arrangement. Thus, total magnitude of the directed portion of coating material in the region where the coating material impinges the substrate(s) (W_{MAX1}) is equal to W_{B1}+a₁+a₁. Using trigonometric formulas, one arrives at the following relationship between the magnitude of the of the directed portion of coating material in the region where the coating material impinges upon the substrate(s): W_{MAX1}=W_{B1}+2(D₁−(L_{B1}+H_{PL}))·(W_{B1}/(L_{B1}+H_{PL})).

The above relationship shows that the magnitude of the directed portion of the divergent stream of coating material is a function of one or more parameters. These parameters are the width of the coating material source, the distance between the surface of the coating material source and the region where the coating material impinges the substrate and the axial length of the blinders. The magnitude of the directed portion of coating material decreases or narrows in response to one or more of the following: (1) a decrease in the width of the coating material source, (2) a decrease in the distance between the surface of the coating material source and the region where the coating material impinges the substrate, and/or (3) an increase in the axial length of the blinders. As is expected, the magnitude of the directed portion of coating material increases or widens in response to the opposite of any one or more of the above parameters. Thus, one can vary these parameters, as well as other geometric parameters, to achieve a directed portion of coating material of a desired magnitude to accommodate a specific coating application. Typically, one would expect and try to achieve the condition that the exit angle of divergence of the directed portion of coating material is such so that a substantial part of the periphery thereof impinges the surface of the substrate(s) received by the substrate holder.

The other coating apparatus shown in FIGS. 12 through 14 depict ways in which the geometric parameters influence the magnitude of the directed portion of coating material in the region where the coating material impinges the substrate(s). In this regard, FIG. 12 is a mechanical schematic (i.e., ray diagram) that depicts a portion of a coating apparatus generally designated as 500. FIG. 12 shows the travel of coating material emitting from a coating material source of a pre-selected dimension and pre-selected distance from the substrate(s) when used in conjunction with a blinder assembly of a pre-selected axial length.

Coating apparatus 500 includes a coating material source (e.g., cathode) 502 that has a surface 504. Coating material source 502 has a peripheral lip 503. The height of peripheral lip 503 is equal to H_{PL}. The width of the surface of the coating material source is W_{T1}, which is the same as the width of the coating material source 402 in the embodiment of FIG. 11.

The apparatus 500 further includes a first blinder 506 that has a proximate end 508 that is proximate to the coating material source and a distal end 510 that is distal from the coating material source. Blinder 506 has an interior surface 512. The apparatus further includes a second blinder 514 that has a proximate end 516 that is proximate to the coating material source and a distal end 518 that is distal from the coating material source. Blinder 514 has an interior surface 520. The blinders 506 and 514 are of an equal axial length L_{B2}. In view of the peripheral lip 503, the blinders 506, 514 extend to a distance L_{B2}+H_{PL} from the surface 504 of the coating material source 502.

In this respect, one should appreciate that the axial length (L_{B2}) of the blinders 506, 514 is less than the axial length (L_{B1}) of the blinders 406, 414 in the embodiment of FIG. 11. The pair of blinders 506, 514 defines between them a window 522 that is at their distal ends. Region 524 is the region in which the coating material impinges upon the substrate(s). The distance between the surface of the coating material source and the region in which the coating material impinges upon the substrate(s) is equal to D₁, which is equal to the distance between the surface of the coating material source and the region in which the coating material impinges upon the substrate(s) in the embodiment of FIG. 11.

When the coating material source 502 is operational, a divergent stream of coating material continually emits from the coating material source. Arrows 530, 532, 534 and 536 schematically represent the divergent stream of coating material. The divergent stream of coating material has a directed portion of coating material, which comprises the coating material that is within the boundary or periphery of the coating material stream as represented by the arrows 534 and 536. These arrows 534 and 536 extend from the corners of the coating material source to the distal ends of the opposite blinders, and thus, represent the periphery of the directed portion of the coating material that exits the blinder assembly. The periphery is oriented at an angle of divergence β₂ relative to the interior surfaces of the blinders. The divergent coating material stream also includes a diverse portion of the coating material. The diverse portion of the coating material comprises the coating material emitted from the coating material source that impinges upon the blinders. The coating material as represented by arrows 530 and 532 is within the diverse portion of coating material.

Consistent with the above-stated formula for the embodiment of FIG. 11, the applicable formula is: W_{MAX2}=W_{B1}+2(D₁−(L_{B2}+H_{PL}))·(W_{B1}/(L_{B2}+H_{PL})). A variation of the axial length of the blinders results in a change of the magnitude of the directed portion of coating material in the region where the coating material impinges the substrate(s). For example, in comparing the magnitudes of the directed portions of coating material of the embodiments of FIG. 11 and FIGS. 12 (i.e., a comparison of W_{MAX1} and W_{MAX2}), a reduction in the axial length of the blinders from L_{B1} to L_{B2} (keeping the other factors the same) results in an increase in the magnitude from W_{MAX1} and W_{MAX2} of the directed portion of coating material in the region where the coating material impinges the substrate(s).

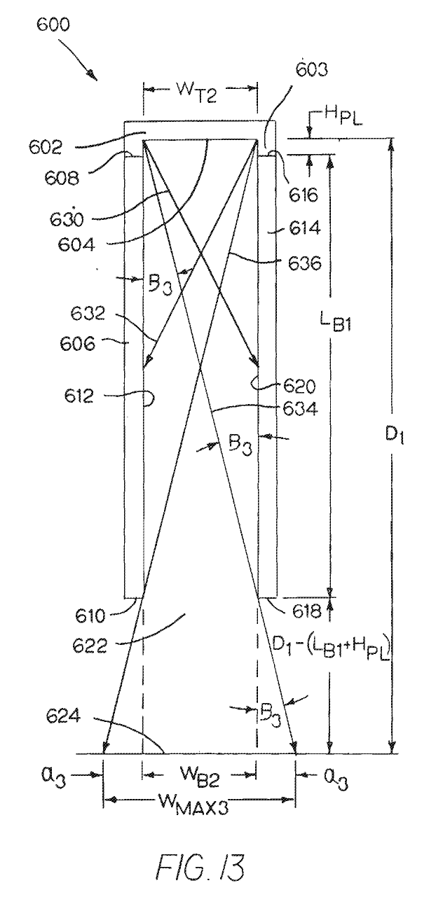

FIG. 13 is a mechanical schematic (i.e., ray diagram) that depicts a portion of a coating apparatus generally designated as 600. FIG. 13 shows the travel of coating material emitting from a coating material source of a pre-selected dimension and pre-selected distance from the substrate(s) when used in conjunction with a blinder assembly of a pre-selected axial length.

Coating apparatus 600 includes a coating material source (e.g., cathode) 602 that has a surface 604. Coating material source 602 has a peripheral lip 603. The height of the peripheral lip 603 is equal to H_{PL}. The width of the surface of the coating material source is W_{T2}, which is less than the width (W_{T1}) of the coating material source 402 in the embodiment of FIG. 11.

The apparatus 600 further includes a first blinder 606 that has a proximate end 608 that is proximate to the coating material source and a distal end 610 that is distal from the coating material source. Blinder 606 has an interior surface 612. The apparatus further includes a second blinder 614 that has a proximate end 616 that is proximate to the coating material source and a distal end 618 that is distal from the coating material source. Blinder 614 has an interior surface 620. The blinders 606 and 614 are of an equal axial length L_{B1}. In this respect, one should appreciate that the axial length of the blinders 606, 614 is equal to the axial length of the blinders 406, 414 in the embodiment of FIG. 11. In view of the peripheral lip 603, the blinders 606, 614 extend a distance equal to L_{B1}+H_{PL} from the surface 604 of the coating material source 602.

The pair of blinders 606, 614 defines between them a window 622 that is at their distal ends. Region 624 is the region in the coating chamber in which the coating material impinges upon the substrate(s). The distance between the surface of the coating material source and the region in which the coating material impinges upon the substrate(s) is equal to D₁, which is equal to the distance between the surface of the coating material source and the region in which the coating material impinges upon the substrate(s) in the embodiment of FIG. 11.

When the coating material source 602 is operational, a divergent stream of coating material continually emits from the coating material source. Arrows 630, 632, 634 and 636 schematically represent the divergent stream of coating material. The divergent stream of coating material has a directed portion of coating material, which comprises the coating material that is within the boundary or periphery as represented by the arrows 634 and 636. These arrows 634 and 636 extend from the corners of the coating material source to the distal ends of the opposite blinders, and thus, represent the periphery of the directed portion of the coating material that exits the blinder assembly. The periphery is oriented at an angle of divergence β₃ relative to the interior surfaces of the blinders. The divergent coating material stream also includes a diverse portion of the coating material. The diverse portion of the coating material comprises the coating material emitted from the coating material source that impinges upon the blinders. The coating material as represented by arrows 630 and 632 is within the diverse portion of coating material.

Consistent with the above-stated formula for the embodiment of FIG. 11, the magnitude of the directed portion of coating material in the region where it impinges the substrate is: W_{MAX3}=W_{B2}+2(D₁−(L_{B1}+H_{PL}))·(W_{B2}/(L_{B1}+H_{PL})). A variation of the width (or dimension) of the coating material source results in a change of the magnitude of the directed portion of coating material in the region where the coating material impinges the substrate(s). For example, in comparing the magnitudes of the directed portions of coating material of the embodiments of FIG. 11 and FIGS. 13 (W_{MAX1} vs W_{MAX3}), a reduction in the width of the coating material source from W_{T1} to W_{T2} (keeping the other factors the same) results in a decrease in the magnitude of the directed portion of coating material in the region where the coating material impinges the substrate(s). A review of FIGS. 11-13 shows the influence various parameters have on the magnitude of the directed portion of coating material. Keeping in mind that the windows 422, 522 and 622 are distal windows that have a distal area and are spaced a distal distance from the surface of the coating material source, it is clear that the directed potion of coating material exhibits a reduction in divergence upon either one or both of the following: the distal distance increase and the distal area decreases.

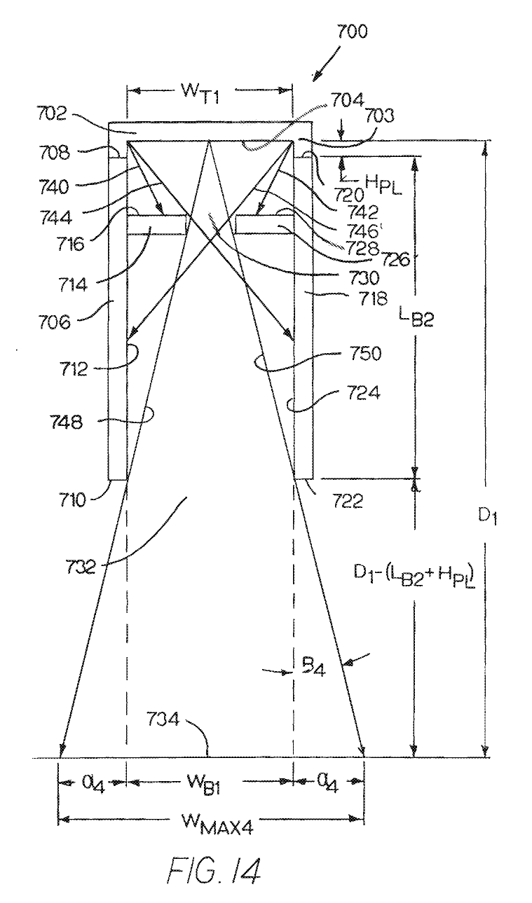

FIG. 14 is a mechanical schematic (i.e., ray diagram) that depicts a portion of a coating apparatus generally designated as 700. FIG. 14 shows the travel of coating material emitting from a coating material source of a pre-selected dimension and pre-selected distance from the substrate when used in conjunction with a blinder assembly of a pre-selected axial length, as well as the blinder assembly presenting a proximate window and distal window through which coating material continually passes. The proximate window and the distal window are spaced apart along the longitudinal axis of the blinder assembly so that the proximate window is closer to the coating material source than is the distal window. As will become apparent from the description below, a part of the diverse portion of coating material and the directed portion of coating material continually pass through the proximate window and the directed portion of coating material continually passes through the distal window.

Coating apparatus 700 includes a coating material source (e.g., cathode) 702 that has a surface 704. Coating material source 702 has a peripheral lip 703. The height of peripheral lip 703 is equal to H_{PL} as shown in FIG. 14. The width of the surface of the coating material source is W_{T1}, which is equal to the width of the coating material source 502 in the embodiment of FIG. 12.

The apparatus 700 further includes a first blinder 706 that has a proximate end 708 that is proximate to the coating material source and a distal end 710 that is distal from the coating material source. Blinder 706 has an interior surface 712. Blinder 706 also contains an interior barrier 714 that projects inward from the interior surface 712. Interior barrier 714 also includes a surface 716.

The apparatus further includes a second blinder 718 that has a proximate end 720 that is proximate to the coating material source and a distal end 722 that is distal from the coating material source. Blinder 718 has an interior surface 724. The blinders 706 and 718 are of an equal axial length L_{B2}. In this respect, one should appreciate that the axial length of the blinders 706, 718 is equal to the axial length of the blinders 506, 514 in the embodiment of FIG. 12. In view of the peripheral lip 703, the blinders 706, 718 extend a distance L_{B2}+H_{PL} from the surface 704 of the coating material source 702. Blinder 718 also contains an interior barrier 726 that projects inward from the interior surface 724. Interior barrier 726 also includes a surface 728. The surfaces (716, 728) of the interior barriers are generally perpendicular to he interior surfaces (712, 724) of their corresponding blinders (706, 718). One should appreciate that these surfaces (716, 728) may be at different angular orientations with respect to the blinders. In addition, the distance between the interior barriers and the coating material source can vary.

The pair of blinders 706, 718 defines between them a pair of windows. One of these windows is a proximate window 730. The proximate window 730 is closer to the coating material source than is the distal window 732. The interior barriers 714 and 726 define therebetween the proximate window 730. The other of these windows is a distal window 732. The blinders 706 and 718 define therebetween at their distal ends the distal window 732. Region 734 is the region in which the coating material impinges upon the substrate(s). The distance between the surface of the coating material source and the region in which the coating material impinges upon the substrate(s) is equal to D₁, which is equal to the distance between the surface of the coating material source and the region in which the coating material impinges upon the substrate(s) in the embodiment of FIG. 12.

When the coating material source 702 is operational, a divergent stream of coating material continually emits from the coating material source. Arrows 740 through 750 represent the divergent stream of coating material. The divergent stream of coating material has a directed portion of coating material, which comprises the coating material that is within the boundary or periphery as represented by the arrows 748 and 750. These arrows (748, 750) extend from the corners of the coating material source to the distal ends of the opposite blinders while also passing through the proximate window 730. These arrows 748, 750 thus define the periphery of the directed portion of the coating material that exits the blinder assembly. The directed portion of coating material has an angle of divergence β₄ relative to the interior walls of the blinders.

The divergent coating material stream also includes a diverse portion of the coating material. The diverse portion of the coating material comprises the coating material emitted from the coating material source that impinges upon the blinders including the interior barriers. The coating material as represented by arrows 740, 742, 744 and 746 is within the diverse portion of coating material. In view of the position of the internal barriers (714, 716) relative to the coating material source and along the axial length of the blinders, a part of the diverse portion of coating material passes through the proximate window 730. Arrows 744 and 746 represents this part of the diverse portion of coating material. The blinders extend past the interior barriers (and proximate window) a sufficient distance so that the coating material as represented by arrows 744 and 746 still impinges upon the blinders and does not pass through the distal window 732.

The inclusion in the blinder assembly of a set of interior barriers results in a reduction in the magnitude of the directed portion of coating material in the region where the coating material impinges the substrate(s). For example, in comparing the magnitudes (W_{MAX4} vs. W_{MAX2}) of the directed portions of coating material of the embodiments of FIG. 12 and FIGS. 14, the use of the interior barriers (keeping the other factors the same) results in a decrease in the magnitude of the directed portion of coating material in the region where the coating material impinges the substrate(s). One should appreciate that the interior barriers may be detachably connected to the interior surfaces of the blinders. In such an arrangement using detachable interior barriers, the magnitude of the directed portion of coating material in the region where the coating material impinges the substrate(s) can be varied by removing the interior barriers or using interior barriers of a different size or inward projection.

In each of the embodiments shown in FIGS. 11-14 the coating material source has width equal to the width between the blinders. One should appreciate that there can be embodiments in which the width of the coating material source is less than the width between the blinders.

As mentioned hereinabove, one aspect of the invention is that the blinders cover approximately at least about fifty percent (50%), and more preferably at least about seventy-five percent (75%), of the distance between the target (i.e., coating material source) and the substrate (e.g., cutting insert) at the substrate's closet approach to the target. Referring to FIG. 12, the positions of the components of the arrangement of the FIG. 12 can be set such that the point of the substrate (or cutting insert) at its closest approach to the target (or cathode or coating material source) is shown in FIG. 12 at point 550. Thus, the distance between the surface 504 of the target 502 and the substrate at its closest approach to the target 502 is D₁. In this specific embodiment, the blinders 506, 514 extended to a distance equal to L_{B2}+H_{PL} from the surface 504 of the target 502 that is equal to about 52% of the distance D₁, which is approximately at least about 50% of the distance D₁. Thus, it is seen that in this specific embodiment there is a blinder means (i.e., a blinder assembly) that extends away from the coating material source and terminates in a distal end located a distal distance away from the coating material source. The substrate is in a condition wherein the substrate is a closest approach distance away from the coating material source. The distal distance is equal to at least about fifty percent of the closet approach distance.

Referring to FIG. 11, the positions of the components of the arrangement of FIG. 11 can be set such that the point of the substrate (or cutting insert) at its closest approach to the target (or cathode or coating material source) is shown in FIG. 11 at point 450. Thus, the distance between surface 404 of the target 402 and the substrate at its closest approach to the target is D₁. In this specific embodiment, the blinders 406, 414 extended to a distance equal to L_{B1}+H_{PL} from the surface 404 of the target 402 that is equal to about 78% of the distance D₁, which is approximately at least about 75% of the distance D₁. Thus, it is seen that in this specific embodiment there is a blinder means (i.e., a blinder assembly) that extends away from the coating material source and terminates in a distal end located a distal distance away from the coating material source. The substrate is in a condition wherein the substrate is a closest approach distance away from the coating material source. The distal distance is equal to at least about seventy-five percent of the closet approach distance.

As used herein, the term “cover”, as well as any grammatical variations thereof, used in connection with the blinders means that the blinders function to impede travel of at least some of the coating stream wherein at least some of the coating stream impinges on the blinders. As an example, in the embodiment of FIG. 12, some of the coating stream impinges on the blinders 506, 514 for approximately at least about 50% of the distance D₁, which is equal to L_{B2}+H_{PL} from the target 502 to the point (550) of the substrate at its closest approach to the target. One can appreciate that the peripheral lip 503, which has a height H_{PL}, has essentially no impact on the coating material plume.

Applicant presents a number of specific examples that demonstrate the advantages and properties of the resultant cutting inserts. These examples are described hereinafter.

Examples 1A, 1B and 1C comprised a coated cutting insert style CNMG432MP. The substrate was a Kennametal Inc. K313 Grade of cobalt-cemented tungsten carbide comprising 6 weight percent cobalt, a small amount of chromium (added as chromium carbide) and the balance tungsten carbide and impurities. The coating scheme comprises alternating nanolayers wherein one nanolayer comprised aluminum titanium nitride and the other nanolayer comprised aluminum titanium chromium nitride.

In regard to the application of the coating scheme, each one of these Examples 1A through 1C was coated via an arc evaporation process using a Metaplas unit MZR 323 made by Metaplas. FIG. 4 shows the general orientation of the targets wherein targets 160-160B were titanium and targets 162-162B were aluminum and targets 164-164B were chromium. The blinders 242-242B and 244-244B were positioned on each side of their corresponding chromium targets as illustrated in FIG. 4. The only difference between Examples 1A through 1C was the distance between the binders. Table 1 below sets forth the distances (in millimeters) between the blinders.

TABLE 1
Narrowest Distance Between the Blinders for Examples 1A through 1C

| | Narrowest Distance Between the Blinders |
|---|---|
| Example | (millimeters) |
| 1A | 40 |
| 1B | 50 |
| 1C | 60 |

In the Examples 1A, 1B and 1C, the distance from the target to an insert at its closest approach to the target was about 15 centimeters (cm). The height of the blinders was about 11.4 cm. Therefore, the blinders covered about seventy-six percent (76%) of the distance between the target and the insert at its closest approach to the target. As mentioned hereinabove, the peripheral lip of the target has essentially no impact on the coating material plume. In these examples 1A, 1B and 1C, the peripheral lip has a height equal to 0.5 cm, and thus, is too small to have an impact on the coating material plume.

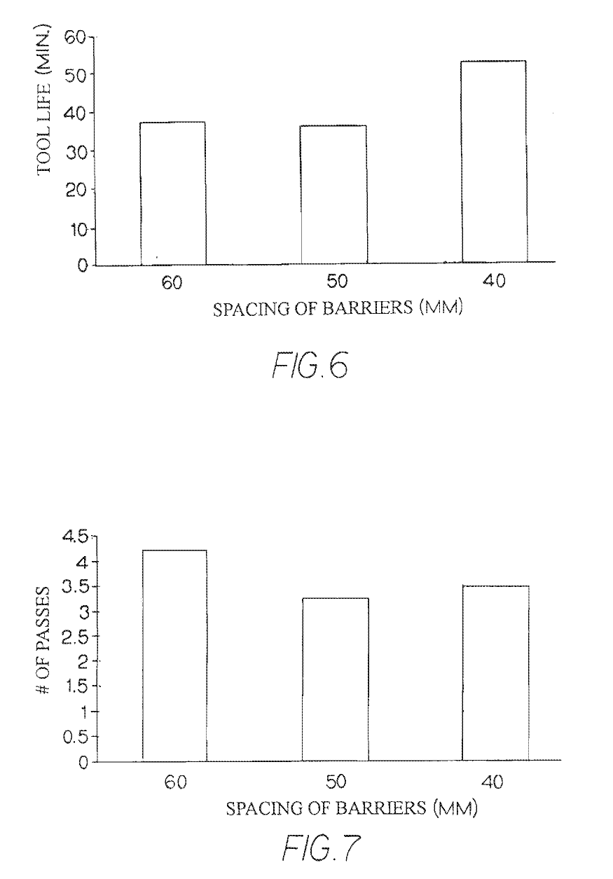

FIG. 6 shows the results of metalcutting tests using Examples 1A through 1C. The turning test parameters were: a workpiece of 316 stainless steel, a speed equal to 650 surface feet per minute (213.3 surface meters per minute), a feed equal to 0.008 inches (0.203 millimeters) per revolution (ipr), a depth of cut equal to 0.100 inches (2.54 millimeters) doc, the cutting insert style of CNMG432MP with a negative 5 degree lead angle and flood coolant.

As can be seen from FIG. 6, the tool life for a turning application as measured in minutes was the greatest when the spacing between the blinders was closest. More specifically, the tool life for a turning application was the greatest for the cutting insert that was coated with the PVD arrangement having the narrowest spacing (40 mm) between the blinders at the chromium target. The tool life for a turning application was about equal for the cutting inserts that were coated with the PVD arrangements wherein the narrowest spacing between the blinders at the chromium target was either 50 mm or 60 mm.

Examples 2A, 2B and 2C comprised a coated cutting insert style OFKT07L6AFENGB. The substrate was a Kennametal Inc. K322 Grade of cobalt-cemented tungsten carbide having a nominal composition comprising about 9.75 weight percent cobalt and the balance tungsten carbide and impurities. The coating scheme comprises alternating nanolayers wherein one nanolayer comprised aluminum titanium nitride with the formula AlₓTi_{y}N and the other nanolayer comprised aluminum titanium nitride with the formula AlₓTi_{y}N. The ratio of x:y varied between the alternating nanolayers.

In regard to the application of the coating scheme, each one of these Examples 2A through 2C was coated via an arc evaporation process using the Metaplas unit made by Metaplas. FIG. 4 shows the general orientation of the targets; however, there were only two sets of targets wherein one set of targets was titanium and the other set of targets was aluminum. The blinders were positioned on each side of their corresponding aluminum targets. The only difference between Examples 2A through 2C was the narrowest distance between the binders. Table 2 sets forth his distances for each example.

TABLE 2
Narrowest Distance Between the Blinders for Examples 2A through 2C

| | Narrowest Distance Between the Blinders |
|---|---|
| Example | (millimeters) |
| 2A | 40 |
| 2B | 50 |
| 2C | 60 |

FIG. 7 shows the results of results of flycut milling tests using Examples 2A through 2C. The test parameters for the face milling of a solid block of 304 stainless steel were a speed equal to 650 surface feet per minute (213.3 surface meters per minute), a feed equal to 0.008 inches (0.203 mm) per revolution (ipr), a depth of cut equal to 0.100 inches (2.54 mm) doc, a radial depth of cut (rdoc) equal to 3 inches (7.62 centimeters), an axial depth of cut (adoc) equal to 0.1 inches (2.54 mm), a pass length equal to 24 inches (60.96 centimeters), and the coolant was dry. The cutting insert style was a OFKT07L6AFENGB style with a lead angle equal to 45 degrees.

FIG. 7 shows that the number of milling passes was the greatest when the spacing between the blinders was the greatest apart. More specifically, the tool life for a milling application was the greatest for the cutting insert that was coated with the PVD arrangement having the widest spacing (60 mm) between the blinders at the chromium target. The tool life for a milling application was about equal for the cutting inserts that were coated with the PVD arrangements wherein the spacing between the blinders at the chromium target was either 50 mm or 40 mm.

For these tests, it appears that the appropriate blinder spacing for a given blinder length to achieve the best metalcutting performance is dependent upon the metalcutting application. For example, in a milling application the wider blinder spacing seems best while in a turning application the narrower blinder spacing appears to be best.

Examples 3A, 3B, 3C and 3D each comprised a coated cutting insert style CNMG432MP. The substrate was a Kennametal Inc. K313 Grade. The coating scheme comprises alternating nanolayers wherein one nanolayer comprised aluminum titanium silicon nitride and the other nanolayer comprised aluminum titanium silicon chromium nitride.

In regard to the application of the coating scheme, each one of these Examples 3A through 3D was coated via an arc evaporation process using the Metaplas unit. FIG. 4 shows the general orientation of the targets and the chromium targets relative to the blinders. In the specific arrangement, there were two chromium targets with blinders associated therewith.

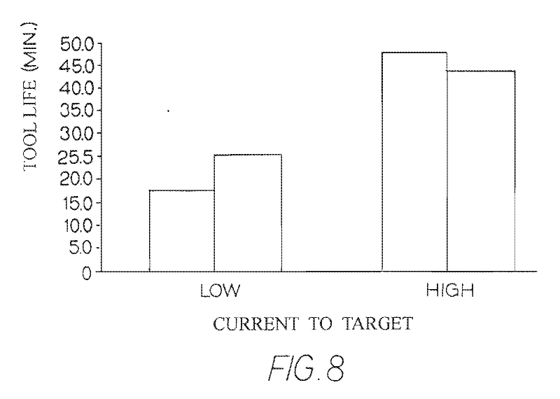

In reference to the test results presented by FIG. 8, Examples 3A and 3B had a current equal to 40 amps (designated as LOW) applied to the chromium targets and Examples 3C and 3D had a current equal to 60 amps (designated as HIGH) applied to the chromium targets. In this PVD arrangement, there were six additional targets wherein each targets comprised 60 atomic percent aluminum, 30 atomic percent titanium, and 10 atomic percent silicon. The electrical current applied to each of these six AlTiSi targets was equal to between 75 amps and 90 amps.

FIG. 8 shows the results of metalcutting tests using Examples 3A through 3D. The turning test parameters were: a workpiece of 316 stainless steel, a speed equal to 650 surface feet per minute (213.3 surface meters per minute), a feed equal to 0.008 inches (0.203 mm) per revolution (ipr), a depth of cut equal to 0.100 inches (2.54 mm) doc, the cutting insert style of CNMG432MP with a negative 5 degree lead angle and flood coolant.

The tool life as measured in minutes was the greatest when the electrical current applied to the chromium targets was the greatest. More specifically, the tool life was the greater for the cutting inserts that were coated using the higher power/current level (i.e., 60 amps) to the chromium targets as compared to using the lower power/current level (i.e., 40 amps) to the chromium targets.

The results presented in FIG. 8 show that the use of blinders, and especially blinders with a smaller minimum spacing, enhance the tool life. In this regard, heretofore, while the use of higher currents to the target resulted in good coating properties, the higher current levels also resulted in more disadvantageous overlap. However, in the present invention, the use of the blinders has reduced the extent of overlap so that it is possible to use higher current to target levels.

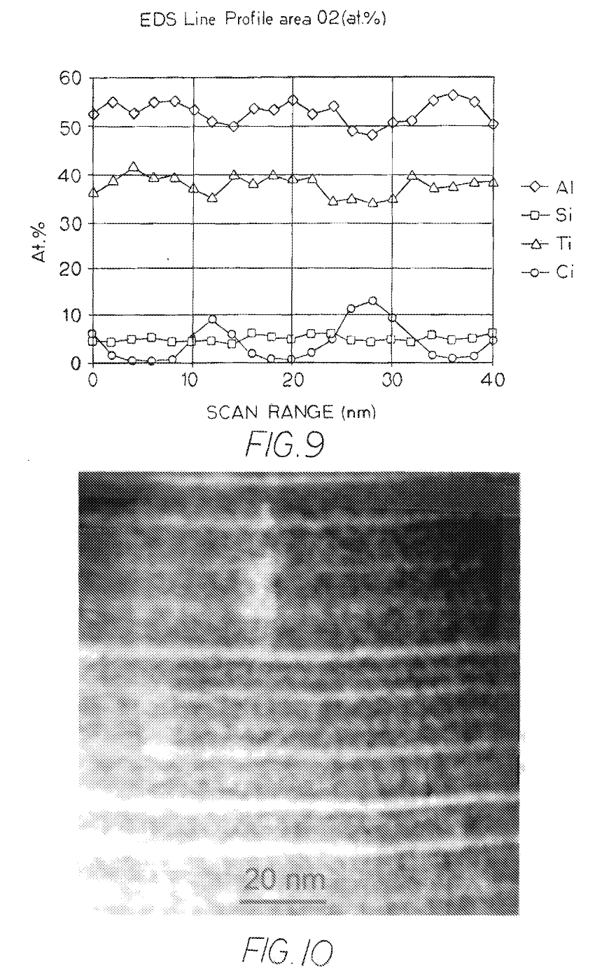

FIG. 9 is a EDS line profile that sets forth the content in atomic percent of aluminum (diamonds), silicon (squares), titanium (triangles) and chromium (circles) over a scan range equal to 40 nanometers for the coating scheme like that of either Example 3C or 3D where the electrical current applied to the chromium targets was equal to 60 amps. FIG. 9 shows a coating scheme that has a plurality of coating sets of alternating nanolayers. The chromium content periodically goes to zero. In light of the variation of the chromium content, it is apparent that one of the alternating layers has a complete absence of chromium. Since chromium exists in the alternate layer, it is apparent that this coating has an alternating layers that contains the metallic element, i.e., chromium, absent from the one alternating layer.

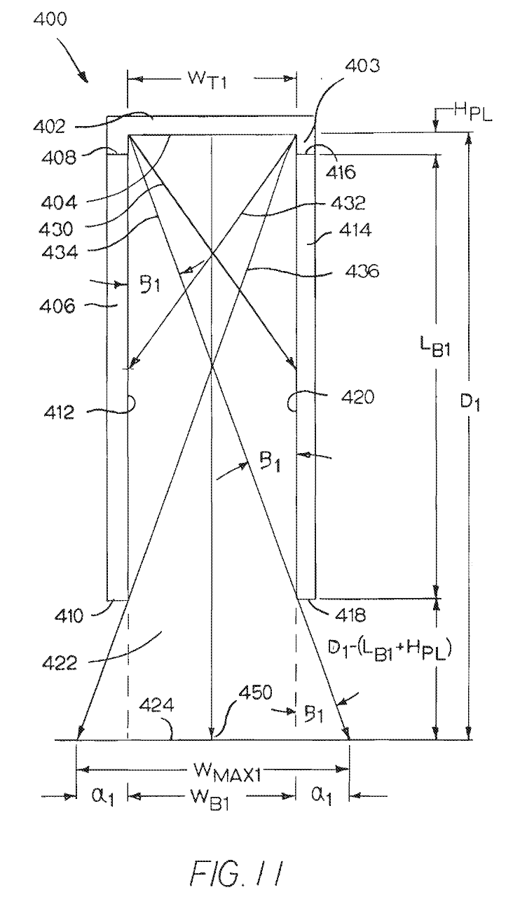

FIG. 10 is a photomicrograph performed via TEM (transmission electron microscopy) of the coating scheme of FIG. 9 and includes a legend of 20 nanometers.

Tests were conducted on Examples 4-8 to ascertain the maximum microhardness and adhesion of the nanolayer coating scheme produced by the targets shown in Table 3 using the Metaplas Unit having a nitrogen/nitriding atmosphere to form a nitride nanolayer. The adherence of the coatings to the substrate of the above examples was tested for coating adherence using an indentation adhesion load test. In this regard, adhesion between the coating and the substrate was determined by an indentation adhesion test using a Rockwell hardness tester with a Rockwell A scale Brale cone shaped diamond indenter at a selected load range of 15 kg, 30 kg, 45 kg, 60 kg, 100 kg and 150 kg. The adhesive strength was defined as the minimum load at which the coating debonded and/or flaked. Examples 4-8 comprised the coating schemes as set forth in Table 3 below.

Table 3 below presents these results for the maximum microhardness (kg/mm²) and the adhesion (kg).

TABLE 3
Maximum Microhardness and Adhesion
Of Examples 4-8

| | | Coating | | |
|---|---|---|---|---|
| | | Thickness | Max Micro | |
| Example | Targets | (μm) | Hardness | Adhesion |
| 4 | AlTi/Ti* | 2-5 μm | ~2900 kg/mm² | 100-150 kg |
| 5 | AlTi/Zr* | 4-5 μm | ~2400 kg/mm² | 100-150 kg |
| 6 | AlTi/Cr* | 4-5 μm | ~2700 kg/mm² | 100-150 kg |
| 7 | AlTiSi/Ti* | 3-5 μm | ~2700 kg/mm² | 100-150 kg |
| 8 | AlTiSi/Cr* | 3-5 μm | ~2900 kg/mm² | 100-150 kg |

*In these examples, the titanium target, zirconium target and chromium target, whichever is applicable, have the blinders around them. The AlTi target and the AlTiSi target did not have blinders around them.

Table 3 also presents the target compositions for each example under the column heading “Targets”. In this regard, the coating of each example comprised a plurality of nanolayer coating sets wherein each nanolayer coating set comprised a pair of different coating compositions produced by the targets set forth in Table 3. Table 3 further presents the overall total thickness in micrometers (μm) of the coating for each example.

The present invention is suitable for use in any coating system that has cathodes mounted on the wall such as, for example, a cathodic arc system, as well as sputtering systems. A wide variety of different coating compositions can be used in conjunction with the present invention.

All of the examples set forth herein used the Metaplas unit. In the Metaplas unit, a cathode is mounted on each wall wherein the walls are orthogonal to one another. There should be an understanding that the present invention is useful in a system that has one wall in which all of the cathodes are mounted on the one wall such as, for example, where all of the cathodes are parallel to each other mounted on one wall. Further, there should be an understanding that the present invention is useful in a system that has one wall in which cathodes of different compositions are mounted on a single wall.

It is apparent that there has been invented an improved coating arrangement (i.e., equipment), as well as an improved method, for the deposition of material via PVD techniques It is also apparent that applicant has invented improved equipment, as well as an improved method, for the deposition using multiple targets (cathodes) of different kinds of material compositions wherein such equipment and method has application to the deposition of nanolayers of material. It is also apparent that applicant's equipment and method are suitable for use in a reactive environment.

It is further apparent that applicant has invented improved equipment, as well as an improved method, for the deposition of material (and especially different material compositions in alternating or sequential or random layers including nanolayers) via PVD techniques wherein the extent of the coating material overlap from coating material plumes is minimized, especially in comparison to earlier techniques, whereby the nanolayers have strong well-defined boundaries therebetween.

It is also apparent that the present invention provides improved equipment, as well as an improved method, for the deposition of nanolayers via PVD techniques wherein such equipment and techniques would allow for the control of the thickness of the nanolayers independent of other operating parameters of the coating reactor (e.g., the level of power to the cathodes, rotational speed of the turntables, the pressure and/or temperature in the chamber, and other like parameters).

The patents and other documents identified herein are hereby incorporated by reference herein.

Other embodiments of the invention will be apparent to those skilled in the art from a consideration of the specification or a practice of the invention disclosed herein. It is intended that the specification and examples are illustrative only and are not intended to be limiting on the scope of the invention. The true scope and spirit of the invention is indicated by the following claims.

What is claimed is:

1. A physical vapor deposition apparatus for coating a substrate, the apparatus comprising:
a substrate holder adapted to receive the substrate;
a coating material source that emits a divergent stream of coating material comprising a diverse portion of coating material and a directed portion of coating material;
a blinder means, positioned to be in operative engagement with the coating material source, for receiving and impacting the divergent stream of coating material so that the directed portion of coating material exits the blinder means traveling generally toward the substrate holder; and
the directed portion of coating material exhibits less divergence than the divergent stream of coating material.

2. The physical vapor deposition apparatus according to claim 1 wherein the blinder means comprises a blinder assembly defining a window through which the directed portion of coating material continually passes.

3. The physical vapor deposition apparatus according to claim 2 wherein the blinder assembly presenting a generally flat surface wherein at least a portion of the diverse portion of coating material impacts the generally flat surface.

4. The physical vapor deposition apparatus according to claim 3 wherein the divergent stream of coating material having a central longitudinal axis, and the generally flat surface being generally parallel to the central longitudinal axis of the divergent stream of coating material.

5. The physical vapor deposition apparatus according to claim 3 wherein the divergent stream of coating material having a central longitudinal axis, and the generally flat surface being generally non-parallel to the central longitudinal axis of the divergent stream of coating material.

6. The physical vapor deposition apparatus according to claim 2 wherein the blinder assembly being closer to the coating material source than the substrate holder.

7. The physical vapor deposition apparatus according to claim 2 wherein the blinder assembly being closer to the substrate holder than the coating material source.

8. The physical vapor deposition apparatus according to claim 2 wherein the blinder assembly presenting a generally arcuate surface wherein at least a portion of the diverse portion of coating material impacts the generally arcuate surface.

9. The physical vapor deposition apparatus according to claim 1 wherein the blinder means comprises a blinder assembly with a distal end, the blinder assembly contains a distal window adjacent to the distal end thereof, and the directed portion of coating material continually passes through the distal window.

10. The physical vapor deposition apparatus according to claim 9 wherein the distal window being positioned a distal distance from the coating material source, and the distal window presenting a distal area; and the directed portion of coating material exhibits a reduction in divergence upon either one or both of the following: the distal distance increases and the distal area decreases.

11. The physical vapor deposition apparatus according to claim 1 wherein the blinder means comprises a blinder assembly that extends away from the coating material source and terminates in a distal end located a distal distance away from the coating material source, and the substrate being in a closest condition wherein the substrate is a closest approach distance away from the coating material source, and the distal distance is equal to at least about fifty percent of the closet approach distance.

12. The physical vapor deposition apparatus according to claim 11 wherein the distal distance is equal to at least about seventy-five percent of the closet approach distance.

13. The physical vapor deposition apparatus according to claim 1 further including a coating chamber, and the coating chamber containing the substrate holder and the coating material source and the blinder means.

14. The physical vapor deposition apparatus according to claim 1 wherein the blinder means comprises a blinder assembly having a longitudinal axis, and the blinder assembly defining at least a proximate window and a distal window spaced apart along the longitudinal axis of the blinder assembly, the proximate window being closer to the coating material source than the distal window; and a part of the diverse portion of coating material and the directed portion of coating material continually passes through the proximate window and the directed portion of coating material continually passes through the distal window.

15. The physical vapor deposition apparatus according to claim 1 wherein the blinder means impacts the divergent stream of coating material so as to continuously block the passage of the diverse portion of coating material from passing out of the blinder means while continuously allowing the directed portion of coating material to exit the blinder means and travel generally toward the substrate holder.

16. The physical vapor deposition apparatus according to claim 1 wherein the substrate holder contains at least one substrate reception region adapted to receive the substrate, and the substrate holder is movable with respect to the coating material source whereby the substrate received by the substrate reception zone is selectively impinged by the directed portion of coating material.

17. The physical vapor deposition apparatus according to claim 16 wherein the substrate being in operative alignment with the coating material source through the blinder means when the substrate is impinged by the directed portion of coating material.

18. The physical vapor deposition apparatus according to claim 1 wherein the directed portion of coating material has a central longitudinal axis and a periphery, the directed portion of coating material exits the blinder means at an exit angle of divergence relative to the central longitudinal axis of the directed portion of coating material.

19. The physical vapor deposition apparatus according to claim 18 wherein the exit angle of divergence is such as that a substantial part of the periphery of the directed portion of coating material impinges the surface of the substrate received by the substrate holder.

20. The physical vapor deposition apparatus according to claim 1 wherein the magnitude of the divergence of the directed portion of coating material is a function of one or more of the following: dimension of the coating material source, axial length of the blinder means, and distance between the surface of the coating material source and the substrate holder.

21. A physical vapor deposition apparatus for applying a coating scheme to a substrate, the apparatus comprising:
a substrate holder adapted to receive the substrate;
a first coating material source that emits a first divergent stream of coating material comprising a first diverse portion of first coating material and a first directed portion of first coating material;
a first blinder means, positioned to be in operative engagement with the first coating material source, for receiving and impacting the first divergent stream of first coating material so that the first directed portion of first coating material exits the first blinder means traveling generally toward the substrate holder;
the first directed portion of first coating material exhibits less divergence than the first divergent stream of first coating material; and
a second coating material source that emits a second divergent stream of second coating material comprising a second diverse portion of second coating material and a second directed portion of second coating material.

22. The physical vapor deposition apparatus according to claim 21 further including:
a second blinder means, positioned to be in operative engagement with the second coating material source, for receiving and impacting the second divergent stream of second coating material so that the second directed portion of second coating material exits the second blinder means traveling generally toward the substrate holder; and
the second directed portion of second coating material exhibits less divergence than the second divergent stream of second coating material.

23. The physical vapor deposition apparatus according to claim 22 wherein the first directed portion of coating material has a first central longitudinal axis and a first periphery, the first directed portion of coating material exits the first blinder means at a first exit angle of divergence relative to the first central longitudinal axis of the first directed portion of coating material, and the first exit angle of divergence is such so that: a substantial part of the first periphery of the first directed portion of coating material impinges the surface of the substrate received by the substrate holder and a minimal amount of the first directed portion of coating material overlaps the second directed portion of coating material exiting the second blinder means.

24. The physical vapor deposition apparatus according to claim 22 wherein the second directed portion of coating material has a second central longitudinal axis and a second periphery, the second directed portion of coating material exits the second blinder means at a second exit angle of divergence relative to the second central longitudinal axis of the second directed portion of coating material, and the second exit angle of divergence is such so that: a substantial part of the second periphery of the second directed portion of coating material impinges the surface of the substrate received by the substrate holder and a minimal amount of the second directed portion of coating material overlaps the first directed portion of coating material exiting the first blinder means.

25. The physical vapor deposition apparatus according to claim 21 wherein the first coating material forms a first coating layer of the coating scheme and the second coating material forms a second coating layer of the coating scheme, and the first coating layer is softer than the second coating layer.

26. A blinder for use in conjunction with a physical vapor deposition apparatus having a coating material source that emits a divergent stream of coating material having a diverse portion of coating material and a directed portion of coating material, the blinder comprising:
a blinder body having a proximate end that receives the divergent stream of coating material, the blinder body further defining a window through which the directed portion of coating material continually passes, and the blinder body having a distal end through which the directed portion of coating material exits the blinder body exhibiting less divergence than the divergent stream of coating material.

27. The blinder according to claim 26 wherein the window comprising a distal window located adjacent to the distal end of the blinder body.

28. The blinder according to claim 27 wherein the distal window being positioned a distal distance from the coating material source, and the distal window presenting a distal area; and the directed portion of coating material exhibits a reduction in divergence upon either one or both of the following: the distal distance increases and the distal area decreases.

29. The blinder according to claim 26 wherein the blinder body having a longitudinal axis, and the blinder body defining at least a proximate window and a distal window spaced apart along the longitudinal axis of the blinder body, the proximate window being closer to the coating material source than the distal window; and a part of the diverse portion of coating material and the directed portion of coating material continually passes through the proximate window and the directed portion of coating material continually passes through the distal window.

30. The blinder according to claim 26 wherein the blinder body impacts the divergent stream of coating material so as to block the passage of the diverse portion of coating material from passing out of the blinder body, and the window allowing the directed portion of coating material to pass therethrough.

31. A method of coating the surface of a substrate by physical vapor deposition comprising the steps of:
providing a substrate holder adapted to receive the substrate;
emitting a divergent stream of coating material from a coating material source wherein the divergent stream of coating material comprising a diverse portion of coating material and a directed portion of coating material; and
providing a blinder that receives the divergent stream of coating material whereby the blinder blocks the diverse portion of coating material from exiting the blinder and allows the directed portion of coating material to exit the blinder traveling generally toward the substrate holder whereby the directed portion of coating material exhibits less divergence than the divergent stream of coating material so that a substantial part of the directed portion of coating material impinges the substrate.

32. A method of coating the surface of a substrate by physical vapor deposition comprising the steps of:
providing a substrate holder adapted to receive the substrate;
emitting a first divergent stream of coating material from a first coating material source wherein the first divergent stream of coating material comprising a first diverse portion of coating material and a first directed portion of coating material;
providing a first blinder that receives the first divergent stream of coating material whereby the first blinder blocks the first diverse portion of coating material from exiting the first blinder and allows the first directed portion of coating material to exit the first blinder traveling generally toward the substrate holder whereby the first directed portion of coating material exhibits less divergence than the first divergent stream of coating material so that a substantial part of the first directed portion of coating material impinges the substrate;
emitting a second divergent stream of coating material from a second coating material source wherein the second divergent stream of coating material comprising a second diverse portion of coating material and a second directed portion of coating material; and
providing a second blinder that receives the second divergent stream of coating material whereby the second blinder blocks the second diverse portion of coating material from exiting the second blinder and allows the second directed portion of coating material to exit the second blinder traveling generally toward the substrate holder whereby the second directed portion of coating material exhibits less divergence than the second divergent stream of coating material so that a substantial part of the second directed portion of coating material impinges the substrate.

33. A physical vapor deposition coated article comprising:
a substrate presenting a surface, and a coating on at least a portion of the surface of the substrate;
the coating comprising a plurality of elements, and each one of the elements being continuously emitted via physical vapor deposition from its separate source; and
the coating comprising a coating set of alternating nanolayers, and one of the alternating nanolayers having an essentially complete absence of one of the continuously emitted elements and another of the alternating nanolayers containing the element absent from the one alternating nanolayers.

34. The coated article of claim 33 wherein said another alternating layer contains each one of the plurality of the metallic elements.

35. The coated article of claim 33 wherein the alternating layers comprise alternating nanolayers.

36. The coated article of claim 33 wherein the coating comprises three of the metallic elements, and each one of the three metallic elements being continuously emitted via physical vapor deposition from its separate source; and one of the alternating layers having an essentially complete absence of one of the metallic elements and another of the alternating layers containing the three metallic elements.

37. The coated article of claim 33 wherein the coating comprises four of the metallic elements, and each one of the four metallic elements being continuously emitted via physical vapor deposition from its separate source; and one of the alternating layers having an essentially complete absence of one of the metallic elements and another of the alternating layers containing the four metallic elements.
